(19) United States
(12) Patent Application Publication
(10) Pub. No.: US 2009/0121800 A1
(43) Pub. Date: May 14, 2009

(54) Apparatus for Low Phase Noise Oscillators

(76) Inventors: Harvey Horowitz, Monroe, NY (US); Bernard Horowitz, Monroe, NY (US)

Correspondence Address: RICHARD B. KLAR, 145 WILLIS AVENUE, SUITE NO. 6, MINEOLA, NY, 11501, US

(21) Appl. No.: 11/792,733

(22) PCT Filed: Dec. 15, 2004
(86) PCT No.: PCT/US04/42575

§ 371 Date: Jun. 8, 2007

Related U.S. Application Data
(60) Provisional application No. 60/530,107, filed on Dec. 16, 2003.

(51) Int. Cl. H03B 7/00

(52) U.S. Cl. 331/132

(57) ABSTRACT

The present invention relates to an oscillator circuit. In the oscillator circuit, the level of the output signal is monitored and compared to a desired reference level. An error signal is then generated and used to modify the feedback so that the negative resistance of the active device presented to the resonator exactly equals the magnitude of the positive resistance of the resonator without having to rely upon saturation in the active device and for very linear operation of the device such that over the full swing of the output, the negative impedance presented to the resonator remain extremely constant—thus reducing the sensitivity of the oscillator to any noise present.

This is a non-provisional application of provisional application Ser. No. 60/530,107 filed on Dec. 16, 2003.

### BACKGROUND OF THE INVENTION

1. Field of the Invention

The present invention relates to a low phase noise oscillator. In particular, the present invention relates to an oscillator circuit wherein the level of the output signal is monitored and compared to a desired reference level and the error signal used to modify the feedback such that the negative resistance of the active device presented to the resonator exactly equals the magnitude of the positive resistance of the resonator without having to rely upon saturation in the active device and for very linear operation of the device such that over the full swing of the output, the negative impedance presented to the resonator remain extremely constant—thus reducing the sensitivity of the oscillator to any noise present.

2. The Prior Art

Typically, oscillators rely upon circuit non-linearities to limit oscillator amplitude. The conditions for oscillation are established with loop gain sufficiency greater than unity so that circuit losses are over come and oscillator amplitude grows until limited by the large signal non-linearities in the particular circuit, while this is a practical solution, it is not the best from the stand point of limiting oscillator phase noise. This approach will tend to limit amplitude variation on the signal output but will adversely effect the phase noise characteristics of an oscillator, which is of far greater importance in most applications—especially communications.

In general, by allowing an oscillator circuit to run in saturation, the phase noise is actually enhanced rather than minimized due to such circuit fluctuations as shot or 1/f noise actually of the active device or resonator (some resonators such as quartz crystals can exhibit 1/f noise—typically less than that of the active device but none the less, non-zero). Several things occur in a typical oscillator circuit which actually enhances phase noise!

1. Typically output amplitude is limited on one end of the output voltage swing by allowing the active device to saturate—while running a typical active device at high current minimizes the effect of the devices shot noise, saturation typically implies allowing the active device to swing to a point where the voltage across it is small; this will enhance device terminal capacitance non-linearities, since in general device terminal capacitance increases markedly at low terminal voltages! This, of course, increases phase noise and enhances the effects of shot noise on the output phase spectrum of the oscillator. On the other end of the output voltage swing, if the devices is allowed to run to little or no current, this typically coincides with maximum terminal voltage which minimizes terminal capacitance non-linearities, but increase the effects and indeed the magnitude of shot or 1/f noise! In the Leeson for calculating the phase noise of an oscillator, mean values the for the change in parameter values as a function of change in voltage are used, since the magnitude of each effect actually varies from one point of the output waveform to the next!

2. Not controlling device gain to be as close to unity as needed to sustain oscillation, also enhances the noise effects, since they are now amplified by the device gain.

### SUMMARY OF THE INVENTION

It is therefore, desirable to provide an apparatus to improve the phase noise characteristics of an oscillator, by doing the following:

A) Allow only linear operation of the circuits; typically utilizing other than non-linear circuit operation to limit output voltage swing.

B) In addition to linear operation of the circuit (i.e. only allowing the oscillation amplitude to swing about the device bias point such that the device is only in its linear region at any point in the voltage swing), any circuit modification that minimizes residual non-linearities over the range of the voltage swing will minimize phase noise.

C) Any circuit configuration that cancels out the effects of shot noise (i.e. the change in any circuit parameter that effects oscillation frequency as a function of noise voltage). Circuit configurations allowing the stable oscillation without relying upon saturation in the active device.

### BRIEF DESCRIPTION OF THE DRAWINGS

FIG. 1 is a block diagram illustrating a standard oscillator circuit; and

FIG. 2 is a block diagram illustrating the improved circuitry of an oscillator circuit according to the present invention.

### DETAILED DESCRIPTION OF THE PREFERRED EMBODIMENT(S)

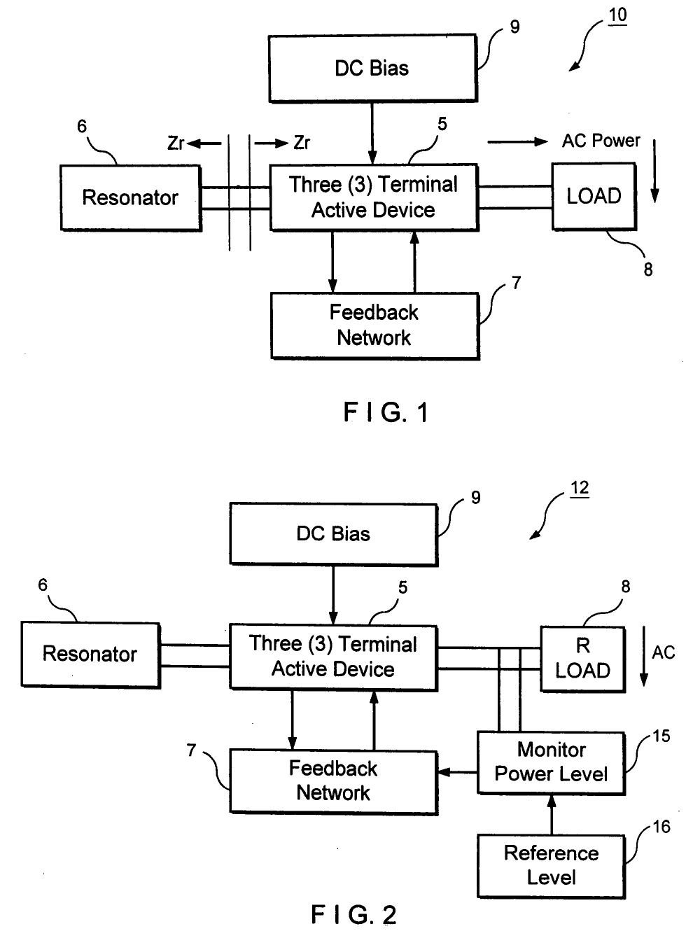

The possible circuit configuration for an oscillator depend upon the nature of the active device—is it a two terminal or multi-terminal device.
A two terminal device can only be operated in a negative resistance or conductance mode. Typically, impart diodes are operated as negative resistance devices and used in series resonant circuits, while Gunn diodes are operated as negative conductance devices and used in parallel resonant circuits. There are, of course, other types of two terminal devices such as tunnel diodes.
Typical examples of multi-terminal devices are silicon bipolar transistors and GaAs field effect transistors. Silicon bipolar transistors and GaAs FETS are 3 terminal devices and can therefore be operated in any one of several modes so as to produce oscillations.
Negative immittance devices (as the two terminal devices above).
Feedback devices—typically, it is more difficult to design a feedback circuit at microwave frequencies, so the 3 terminal device is commonly operated as a negative immittance device rather than a feedback device at the high frequencies, though of course, this need not be the case.
Referring now to the drawings, consider, by way of example, FIG. 1 of the drawings which illustrates a functional diagram used to represent a 3-terminal device (5) in a negative immittance mode. In this mode, the biased transistor (9) develops gain over the desired frequency range, and feedback is applied to the transistor (in any of the number of ways) so that a negative immittance appears at any one or more of its terminals, but especially at the terminal(s) where the resonator (6) is connected.

When operated as above, it is possible to develop equations which governs the conditions for oscillation to begin as well as equations for steady state operation.

1)1 Start oscillation conditions.

Re[Z_{┌}]s|Re[Z_{†}]|
where Re [Z_{†}]<0.0 and lm [Z_{┌}]=−lm [Z_{†}]

1)2 Steady state oscillation conditions:

Re[Z_{┌}=|Re[Z_{†}(Pout)]|
where Re [Z_{†}]<0.0 and lm [Z_{┌}]=−lm [Z_{†}]
   In other words:

Oscillation begins with the magnitude of the negative resistance of the active device (5) with feedback is greater than the positive resistance of the resonator (6) and when the reactance of the resonator (6) is equal in magnitude and opposite in sign from the reactance of the active device(5) with feedback(7).

The oscillator steady state power output is reach when the negative resistance of the active device (5) with feedback (7) has been reduced by saturation to a value exactly equal in magnitude and opposite in sign to the resistance of the resonator(7).

Referring now to FIG. 2 of the drawings, FIG. 2 illustrates how the circuit of FIG. 1 has been modified to reflect the teaching of the present invention.

In the circuit (12) of FIG. 12, means (15) are provided for the level of the output signal to be monitored and compared to a desired reference level (16) and for an error signal to be generated and used to modify the feedback in the feedback network (7) so that the negative resistance of the active device (5) presented to the resonator (6) exactly equals the magnitude of the positive resistance of the resonator (6) without having to rely upon saturation in the active device (5) to do so. This circuit (12) also allows the output amplitude in steady state operation to be arbitrarily small and also allows for very linear operation of the device (5) so that over the full swing of the output, the negative impedance presented to the resonator (6) remain extremely constant—thus reducing the sensitivity of the oscillator to any noise present. Furthermore, as stated earlier, circuit configurations which minimize the effects of shot and white noise on the value of the negative impedance presented to the active device (5) will further reduce phase noise at the output of the oscillator by minimizing the modulation of the negative impedance by said noise. For example, a balanced configuration for the active devices with the resonator connected in a differential manner, the differential pair fed by a low noise high compliance current source will serve to greatly reduce the modulation of the negative impedance seen by the resonator and hence the phase noise spectrum of the oscillator. It should be noted that a differential configuration has been used in the past for integrated mos oscillators to reduce their otherwise very high phase noise to an acceptable level. However, without the innovation presented here, the full benefits of such a configuration have never been achieved since allowing saturation mitigates much to the benefits of the differential configuration:
Operation of the resonator in the feedback mode (series or parallel operation of the resonator) utilizes the forward gain of the active device to compensate for the positive resistance (i.e. loss) of the resonator. Again, instead of allowing saturation to limit signal amplitude, any of a variety of means to limit the forward gain (with minimal phase shift so as not to change the resonant frequency unduly) can be used, thereby allowing the circuit to run in the steady state with an arbitrarily small output swing, such operation makes it possible to achieve very low phase noise as discussed previously.

The process shown can occur at the RF frequency with out “detecting” the level of the signal and running the controls signals at base band (for example, using a suitable yig resonator properly biased so that it limits signal amplitude as the feedback element in a bipolar oscillator).

Further, while meeting the conditions for oscillation, the forward gain can be set low as to minimize the sensitivity of the negative impedance presented to noise in the active device.

All of the preceding not withstanding should not detract from the fundamental point that to make an oscillator with very low phase noise requires a system to be as linear as possible. All the methods presented here are but examples of ways to achieve this end and do not detract from many other proper ways to implementing this fundamental idea.

Another example of an oscillator with low noise properties is one utilizing YIG material which exhibits material specific limiting utilizing YIG as the tank circuit in an oscillator would permit one to construct a feedback an oscillator that operates in the linear region and thus achieves low phase noise operation.

Although the present invention has been described in terms of the presently preferred embodiments, it is to be understood that the disclosure is not to be interpreted as limiting. Various alterations and modifications will no doubt become apparent to those skilled in the art after having read the above disclosure. Accordingly, it is intended that the appended claims be interpreted as covering all alterations and modifications as fall within the true spirit and scope of the invention.

1. An apparatus for operating an oscillator in saturation while limiting phase noise and shot noise, comprising:
an oscillator circuit including a resonator, an active device, and a feedback device;
means for monitoring and comparing an output signal of said oscillator circuit to a desired reference level and for generating an error signal to modify a feedback signal of feedback device to said oscillator circuit so that a negative resistance of said active device presented to said resonator equals a magnitude of a positive resistance of said resonator without relying upon saturation in said active device thereby permitting linear operation of said active device so that over a full swing of said output, a negative impedance presented to said resonator remains extremely constant.

2. The apparatus according to claim 1 wherein said active device has three terminals.
